(19) United States
(12) Patent Application Publication
(10) Pub. No.: US 2026/0004998 A1
(43) Pub. Date: Jan. 1, 2026

(54) PLASMA PROCESSING APPARATUS AND REACTION TUBE WALL PROTECTION MEMBER

(71) Applicant: Tokyo Electron Limited, Tokyo (JP)

(72) Inventor: Hiroyuki MATSUURA, Iwate (JP)

(21) Appl. No.: 19/242,912

(22) Filed: Jun. 18, 2025

(30) Foreign Application Priority Data
Jun. 27, 2024 (JP) 2024-104135

(51) Int. Cl. H01J 37/32

(52) U.S. Cl. CPC H01J 37/32495; H01J 37/32559; H01J 37/32568; H01J 2237/332; H01J 2237/334

(57) ABSTRACT

A plasma processing apparatus includes: a tubular reaction tube; a substrate holder that holds a plurality of substrates stacked in multiple stages and to be inserted into and removed from the reaction tube; a pair of electrodes disposed outside the reaction tube and arranged to face each other across a center of the reaction tube; a radio-frequency power supply that generates plasma in the reaction tube by applying radio-frequency power to both or one of the pair of electrodes; and a pair of reaction tube wall protection members including first and second reaction tube wall protection members. The pair of reaction tube wall protection members cover respective inner wall surfaces of the reaction tube that are opposite to outer wall surfaces of the reaction tube on which the pair of electrodes are installed.

### CROSS-REFERENCE TO RELATED APPLICATIONS

This application is based on and claims priority from Japanese Patent Application No. 2024-104135, filed on Jun. 27, 2024, with the Japan Patent Office, the disclosure of which is incorporated herein in its entirety by reference.

### TECHNICAL FIELD

The present disclosure relates to a plasma processing apparatus and a reaction tube wall protection member.

### BACKGROUND

Japanese Patent No. 4329403 discloses a plasma processing apparatus including a plasma generation unit that extends in a height direction of a reaction tube. Japanese Patent No. 4329403 also discloses that the plasma generation unit includes a hollow protrusion and a pair of plasma electrodes disposed on a pair of wall surfaces of the hollow protrusion. Furthermore, Japanese Patent No. 4329403 discloses that, due to sputtering or etching by plasma, significant stress occurs along the contours of the plasma electrodes and in the vicinity thereof on the wall surfaces of the hollow protrusion.

### SUMMARY

According to an aspect, a plasma processing apparatus includes: a tubular reaction tube; a substrate holder that hold a plurality of substrates stacked in multiple stages and to be inserted into and removed from the reaction tube; a pair of electrodes disposed outside the reaction tube and arranged to face each other across a center of the reaction tube; a radio-frequency power supply configured to generate plasma in the reaction tube by applying radio-frequency power to the pair of electrodes or to one of the pair of electrodes; and a pair of reaction tube wall protection members including a first reaction tube wall protection member disposed between one of the pair of electrodes and the substrate holder, and a second reaction tube wall protection member disposed between a remaining one of the pair of electrodes and the substrate holder. The pair of reaction tube wall protection members are configured to cover respective inner wall surfaces of the reaction tube that are opposite to outer wall surfaces of the reaction tube on which the pair of electrodes are installed.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a vertical cross-sectional view illustrating an example of a plasma processing apparatus.

FIG. 2 is a vertical cross-sectional view taken in the direction of arrow A, illustrating an example of the plasma processing apparatus.

FIG. 3 is a transverse cross-sectional view taken along line B-B, illustrating an example of the plasma processing apparatus.

FIG. 4 is a vertical cross-sectional view of a reaction tube in which a reaction tube wall protection member is disposed.

FIG. 5 is a front view of the reaction tube wall protection member as viewed from a radially outside of the reaction tube.

FIG. 6 is a top view of the reaction tube wall protection member.

FIG. 7 is a transverse cross-sectional view illustrating an example of an arrangement of the reaction tube and the reaction tube wall protection member.

FIG. 8 is a graph illustrating examples of Paschen curves.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of the present disclosure will be described with reference to the accompanying drawings. In each of the drawings, the same components may be denoted by the same reference numerals, and redundant descriptions thereof may be omitted.

### [Plasma Processing Apparatus]

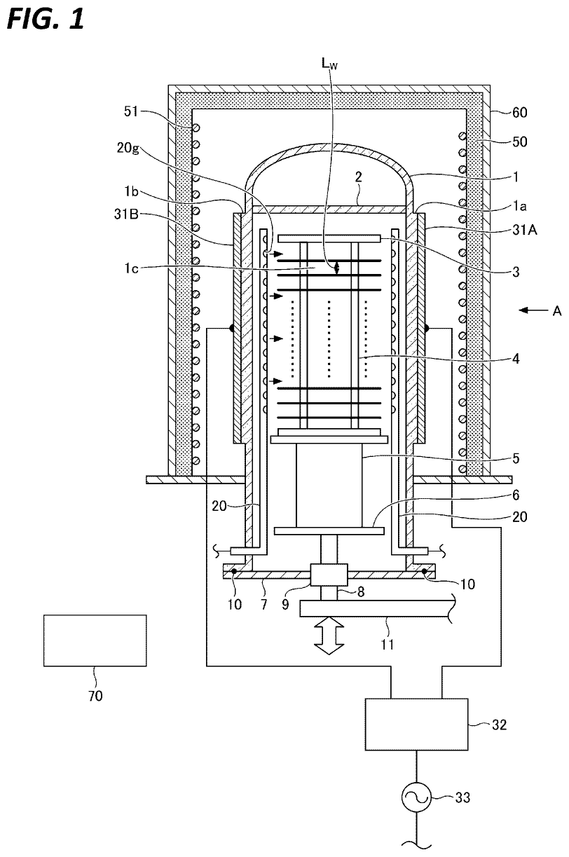

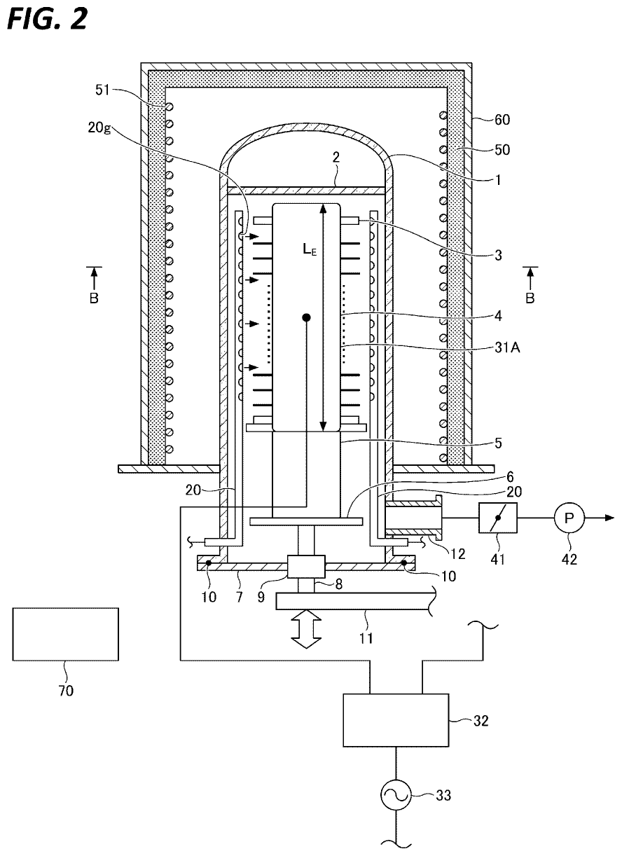

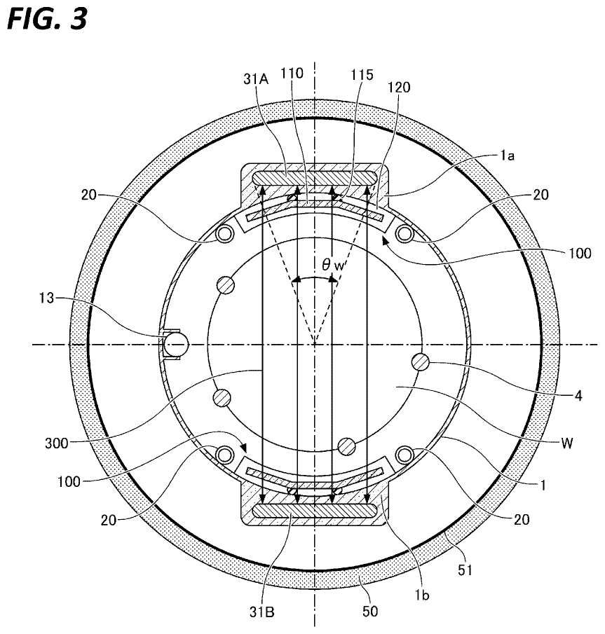

A plasma processing apparatus (substrate processing apparatus) according to the present embodiment will be described with reference to FIGS. 1 to 3. FIG. 1 is a vertical cross-sectional view illustrating an example of a plasma processing apparatus. FIG. 2 is a vertical cross-sectional view taken in the direction of arrow A in FIG. 1, illustrating an example of the plasma processing apparatus. FIG. 3 is a transverse cross-sectional view taken along line B-B in FIG. 2, illustrating an example of the plasma processing apparatus. The plasma processing apparatus illustrated in FIGS. 1 to 3 is a batch-type plasma processing apparatus configured to perform substrate processing (e.g., film formation) on a plurality of substrates W. In FIGS. 1 and 2, illustration of a reaction tube wall protection member 100 (reaction tube wall protection plate 110), which will be described later, is omitted.

The plasma processing apparatus includes a cylindrical reaction tube (also referred to as a “processing container or reactor”) 1 having a ceiling and an open lower end. The entire reaction tube 1 is formed of, for example, quartz. A ceiling plate 2 formed of quartz is provided near the upper end inside the reaction tube 1, and a region below the ceiling plate 2 is sealed.

The reaction tube 1 has a tubular shape (e.g., a cylindrical shape) that is closed at the top. The lower end of the reaction tube 1 is open, and from the lower side of the reaction tube 1, a wafer boat (substrate holder) 3, on which a large number of semiconductor wafers (e.g., several to about 100 wafers) (hereinafter referred to as “substrates W”) as substrates to be processed are stacked in multiple stages, is inserted into and removed from the reaction tube 1. In this way, inside the reaction tube 1, a large number of substrates W are accommodated substantially horizontally along the vertical direction, with a space 1c having a spacing Lw. The wafer boat 3 is made of, for example, quartz. The wafer boat 3 includes four rods 4 (see, e.g., FIG. 3; only two rods are illustrated in FIGS. 1 and 2), and the large number of substrates W are supported by grooves (not illustrated) formed in the rods 4.

The wafer boat 3 is placed on a table 6 via a heat-retaining cylinder 5 made of quartz. The table 6 is supported on a rotary shaft 8 that penetrates a lid 7 made of metal (e.g., stainless steel) and configured to open and close the lower opening of the reaction tube 1.

A magnetic fluid seal 9 is provided at the penetration portion of the rotary shaft 8 to hermetically seal the rotary shaft 8 while allowing it to rotate. A sealing member 10 is provided between the peripheral portion of the lid 7 and the lower end of the reaction tube 1 to maintain the airtightness of the interior of the reaction tube 1.

The rotary shaft 8 is attached to a distal end of an arm 11 supported by an elevating mechanism (not illustrated), such as a boat elevator, and the wafer boat 3 and the lid 7 move up and down integrally, and are inserted into and removed from the reaction tube 1. The table 6 may be fixed to the lid 7 side such that processing of the substrates W is performed without rotating the wafer boat 3.

The plasma processing apparatus also includes a gas supply unit that supplies a predetermined gas, such as a processing gas or a purge gas, into the reaction tube 1.

The gas supply unit includes a gas supply pipe 20. The gas supply pipe 20 is made of, for example, quartz, and extends inward through a side wall of the reaction tube 1 and is bent upward to extend vertically. A vertical portion of the gas supply pipe 20 includes a plurality of gas holes 20g formed at predetermined intervals over a length corresponding to the wafer support range of the wafer boat 3 in the vertical direction. Each gas hole 20g ejects gas in a horizontal direction. A processing gas is supplied to the gas supply pipe 20 from a gas source (not illustrated) via a gas line. The gas line is provided with a flow controller (not illustrated) and an opening/closing valve (not illustrated). Accordingly, the processing gas from the gas source is supplied into the reaction tube 1 through the gas line and the gas supply pipe 20. The flow controller is configured to control a flow rate of the gas supplied from the gas supply pipe 20 into the reaction tube 1. The opening/closing valve is configured to control the supply and shutoff of the gas from the gas supply pipe 20 into the reaction tube 1.

In FIG. 3, four gas supply pipes 20 are illustrated, but the number of gas supply pipes 20 is not limited thereto. The four gas supply pipes 20 may be respectively configured to supply different gases into the reaction tube 1, or at least two or more of the gas supply pipes 20 may be configured to supply the same gas into the reaction tube 1.

Outside the reaction tube 1, a pair of electrodes 31A and 31B are provided. The pair of electrodes 31A and 31B are respectively formed as flat plates and are installed on electrode installation portions 1a and 1b provided outside the reaction tube 1. The pair of electrodes 31A and 31B are disposed to face each other with respect to the center of the reaction tube 1 (i.e., the centers of the substrates W supported by the wafer boat 3). That is, the electrodes 31A and 31B are disposed at positions that are rotated 180° from each other in the circumferential direction of the reaction tube 1. The pair of electrodes 31A and 31B are disposed in parallel with each other. The electrode installation portions 1a and 1b may be formed integrally with the reaction tube 1 or may be formed as separate components.

The electrodes 31A and 31B are made of a good conductor such as metal. The electrodes 31A and 31B may be made of a nickel alloy. By using a nickel alloy as the material for the electrodes 31A and 31B, the influence of metal contamination (i.e., diffusion of metal atoms into the reaction tube 1 made of quartz) may be suppressed compared with using copper as the electrode material. In addition, the nickel alloy has high heat resistance which allows use within a usable temperature range of the plasma processing apparatus (i.e., the temperature to which the plasma processing apparatus is heated by a heating mechanism 50 to be described later, for example, in a range from room temperature to about 900° C.). The nickel alloy also has oxidation resistance.

Each of the electrodes 31A and 31B is connected to a radio-frequency power supply 33 via an impedance matching box 32. The radio-frequency power supply 33 and the impedance matching box 32 constitute a radio-frequency control system. The radio-frequency control system applies impedance-matched radio-frequency power to each of the electrodes 31A and 31B. The radio-frequency power applied from the impedance matching box 32 to the electrodes 31A and 31B has, for example, voltages in opposite phases (e.g., with a phase difference of 180°), and the same voltage amplitude and frequency. In other words, the matching circuit of the impedance matching box 32 is configured such that the voltages are in opposite phases (i.e., with a phase difference of) 180° and have the same voltage amplitude and frequency. This allows a high Vpp (peak-to-peak value of electrode voltage) to be obtained with low power. Although FIGS. 1 and 2 illustrate a configuration in which radio-frequency power is supplied to each of the electrodes 31A and 31B from a single impedance matching box 32 and a single radio-frequency power supply 33, the present disclosure is not limited to this configuration. A configuration may be employed in which an impedance matching box 32 and a radio-frequency power supply 33 configured to supply radio-frequency power to the electrode 31A, and another impedance matching box 32 and radio-frequency power supply 33 configured to supply radio-frequency power to the electrode 31B, may be separately provided. Alternatively, in the pair of electrodes 31A and 31B, radio-frequency power may be supplied from the radio-frequency power supply 33 to one electrode 31A via the impedance matching box 32, and the other electrode 31B may be grounded.

The power supply lines of the electrodes 31A and 31B may be connected to the centers of the electrodes. This allows radio-frequency power to be applied to the centers of the electrodes 31A and 31B.

The frequency of the radio-frequency power applied to the electrodes 31A and 31B may be in a range from 1 kHz to 100 MHz. In addition, in order to suppress the influence of the wavelength of a voltage standing wave generated on the electrodes on film formation (substrate processing), a frequency of 40 MHz or lower may be used.

The inside of the reaction tube 1 is evacuated by an exhaust device 42 (described later) and maintained under a reduced pressure (vacuum atmosphere). In addition, a processing gas is supplied into the reaction tube 1 from the gas supply pipe 20. In the meantime, the outside of the reaction tube 1 is in an atmospheric environment. The electrodes 31A and 31B are disposed in the atmospheric space outside the reaction tube 1.

By applying radio-frequency power from the radio-frequency power supply 33 to each of the electrodes 31A and 31B, an electric field is formed inside the reaction tube 1, and a capacitively-coupled plasma (CCP) is generated therein. The plurality of substrates W inside the reaction tube 1 are held with a space therebetween in the vertical direction by the wafer boat 3. By applying radio-frequency power to the electrodes 31A and 31B, a capacitively-coupled plasma is generated inside the reaction tube 1. That is, plasma is generated in the space between adjacent substrates W. Here, the distance Lw between adjacent substrates W may be 10 mm or more. This may improve in-plane uniformity of the plasma generated in the space between adjacent substrates W. Considering the productivity of substrate processing by the plasma processing apparatus and the size of the reaction tube 1, the distance between adjacent substrates may set to a range of 15 mm to 40 mm.

As illustrated in FIGS. 1 and 2, the electrodes 31A and 31B are disposed to extend over a vertical range that is greater than the vertical range of the plurality of substrates W placed on the wafer boat 3. In other words, the vertical extent LE of the electrodes 31A and 31B is greater than the vertical range of the plurality of substrates W placed on the wafer boat 3. That is, the electrodes 31A and 31B extend to a position above the uppermost substrate W placed on the wafer boat 3 and to a position below the lowermost substrate W placed on the wafer boat 3.

As illustrated in FIG. 3, in the width direction (horizontal direction), the electrode 31A has an angle θw formed between lines connecting the center of the reaction tube 1 (i.e., the centers of the substrates W supported by the wafer boat 3) to opposite ends of the electrode 31A in the horizontal direction is in a range of 20° to 60°. The angle θw may be in a range of 25° to 40°.

The width of the electrode 31B is equal to the width of the electrode 31A. The pair of electrodes 31A and 31B are arranged to face each other with respect to the center of the reaction tube 1 (i.e., the centers of the substrates W supported by the wafer boat 3), and are also arranged in parallel with each other. Accordingly, the direction 300 of the electric field formed by the two electrodes 31A and 31B is indicated by arrow in FIG. 3. As illustrated in FIG. 3, a uniform electric field may be formed on the substrates W.

In addition, in the relationship between the heating mechanism 50 (heater wire 51) described later and the reaction tube 1, the electrodes 31A and 31B block radiant heat from the heating mechanism 50 (heater wire 51) toward the reaction tube 1. Therefore, the circumferential length of the reaction tube 1 that is shielded by the electrodes 31A and 31B may be, for example, ⅓ or less of the entire circumference. In other words, for example, the angle θw may be 60° or less. In addition, in consideration of, for example, the power density of the electrodes 31A and 31B, the angle θw may be in a range of 25° to 60°.

An exhaust port 12 for vacuum evacuation of the interior of the reaction tube 1 is provided in a side wall portion of the reaction tube 1. A pressure control valve 41 configured to control the pressure inside the reaction tube 1 and an exhaust device (exhaust unit) 42 including, for example, a vacuum pump are connected to the exhaust port 12, and the interior of the reaction tube 1 is evacuated through an exhaust pipe by the exhaust device 42.

In addition, inside the reaction tube 1, a thermocouple 13 (see, e.g., FIG. 3) is disposed along the inner wall surface of the reaction tube 1. A plurality of thermocouples 13 is provided in the vertical direction. A control unit 70 detects the temperature using the thermocouples 13, and the detected temperature is used for controlling the temperature of the substrates W.

As illustrated in FIG. 3, the gas supply pipe 20 and the thermocouples 13 are disposed so as to avoid the electric field (the range of electric field direction 300) formed by the electrodes 31A and 31B.

A cylindrical heating mechanism 50 is provided around the reaction tube 1. The heating mechanism 50 includes a wound heater wire 51. The heater wire 51 is arranged so as to surround the reaction tube 1 and the plurality of electrodes 31A and 31B. A space between the heating mechanism 50 and the reaction tube 1 is in an atmospheric environment, and the electrodes 31A and 31B are disposed in this space. The heating mechanism 50 heats the reaction tube 1 and the substrates W therein. The heating mechanism 50 is controlled such that the temperature of the reaction tube 1 reaches a desired temperature. Accordingly, the substrates W inside the reaction tube 1 are heated, for example, by radiant heat from the wall surface of the reaction tube 1. The temperature of the reaction tube 1 heated by the heating mechanism 50 is, for example, in a range from room temperature to 900° C. During film formation, the temperature of the reaction tube 1 is, for example, in a range from 150° C. to 600° C. As an example, in the film formation, the temperature of the reaction tube 1 may be, in a range from 200° C. to 500° C.

A shield 60 is provided outside the heating mechanism 50. That is, the shield 60 is disposed so as to surround the reaction tube 1, the plurality of electrodes 31A and 31B, and the heating mechanism 50. The shield 60 is made of, for example, a good conductor such as metal, and is grounded.

The plasma processing apparatus also includes a control unit 70. The control unit 70 controls operations of respective components of the plasma processing apparatus, such as supply and shutoff of respective gases by opening and closing valves, control of gas flow rates by a flow controller, and control of exhaust by the exhaust device 42. The control unit 70 also performs, for example, on/off control of the radio-frequency power from the radio-frequency power supply 33 and control of the temperature of the reaction tube 1 and the substrates W therein by the heating mechanism 50.

The control unit 70 may be, for example, a computer. A program for performing operations of the respective components of the plasma processing apparatus is stored in a storage medium. The storage medium may be, for example, a flexible disk, a compact disk, a hard disk, a flash memory, or a DVD.

With such a configuration, the plasma processing apparatus may reduce the pressure inside the reaction tube 1 by the exhaust device 42, supply a processing gas into the reaction tube 1 through the gas supply pipe 20, and generate a capacitively-coupled plasma (CCP) in the reaction tube 1 by applying radio-frequency power to the electrodes 31A and 31B so as to perform processing (e.g., film formation or etching) on the substrates W. In addition, the capacitively-coupled plasma is also generated in the space 1c between adjacent substrates W. This improves the uniformity of radicals and active species generated by the plasma at the central portion and the peripheral portion of each of the substrates W. Furthermore, radicals and active species at a concentration sufficient for substrate processing may be generated at the central portion and the peripheral portion of each of the substrates W and supplied thereto.

Here, as illustrated in FIGS. 1 to 3, in the plasma processing apparatus according to the present embodiment, the electrodes 31A and 31B are installed on opposite sides of the reaction tube 1, and plasma is generated inside the reaction tube 1.

The plasma formed inside the reaction tube 1 is a capacitively-coupled plasma (CCP). Accordingly, the inner wall surfaces of the electrode installation portions 1a and 1b of the reaction tube 1 are damaged by the plasma. Specifically, the inner wall surfaces of the electrode installation portions 1a and 1b of the reaction tube 1 are damaged by, for example, ion sputtering or ion-assisted etching. In particular, when the gas used to generate plasma does not contain oxygen and contains hydrogen, significant stress is locally generated at the boundary between a plasma-damaged portion and an undamaged portion in the vicinity thereof.

This stress occurs at an inner end portion of the inner wall surface layer, having a thickness of several hundred micrometers, which has been damaged by plasma, and is locally present within a thickness of 100 μm to 200 μm. Such locally generated significant stress may cause the reaction tube 1, which is made of quartz, to become damaged, and have a shortened service life.

In contrast, in the plasma processing apparatus according to the present embodiment, as illustrated in FIG. 3, a reaction tube wall protection member 100 is provided inside the reaction tube 1. The reaction tube wall protection member 100 is disposed along the inner wall surfaces of the electrode installation portions 1a and 1b where the electrodes 31A and 31B are installed. That is, between the pair of electrodes 31A and 31B disposed to face each other, one reaction tube wall protection member 100 is disposed between the substrates W and the electrode installation portion 1a where the electrode 31A is provided, and the other reaction tube wall protection member 100 is disposed between the substrates W and the electrode installation portion 1b where the electrode 31B is provided. This prevents ions from the plasma formed on the substrates from entering the inner wall surfaces of the electrode installation portions 1a and 1b of the reaction tube 1 and suppresses consumption of the reaction tube 1.

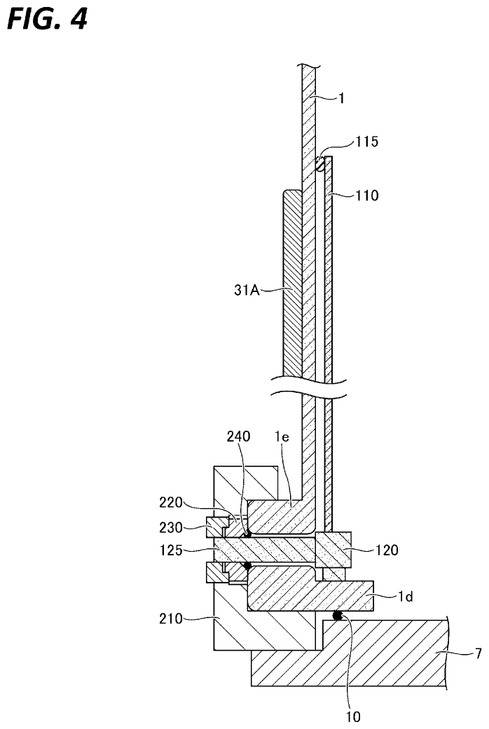

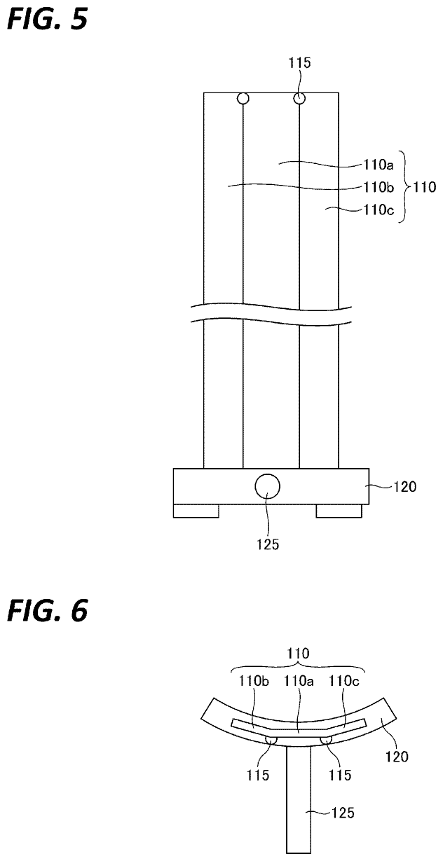

The reaction tube wall protection member 100 will be further described with reference to FIGS. 4 to 6. FIG. 4 illustrates an example of a vertical cross-sectional view of the reaction tube 1 in which the reaction tube wall protection member 100 is disposed. FIG. 5 illustrates an example of a front view of the reaction tube wall protection member 100 as viewed from the radial outside of the reaction tube 1. FIG. 6 illustrates an example of a top view of the reaction tube wall protection member 100. In the following description, the reaction tube wall protection member 100 provided on the side of the electrode installation portion 1a will be described as an example. However, the reaction tube wall protection member 100 provided on the side of the electrode installation portion 1b has the same structure, and a redundant description thereof is omitted.

The reaction tube wall protection member 100 includes a reaction tube wall protection plate 110, protrusions 115, a pedestal 120, and a fixing shaft 125. Among the surfaces of the reaction tube wall protection plate 110, the surface facing the center of the reaction tube 1 is referred to as a front surface, and the surface facing the inner wall surface of the reaction tube 1 is referred to as a rear surface.

The reaction tube wall protection plate 110 is a component that is separate and independent from the side wall surface of the reaction tube 1, and is made of synthetic quartz glass having an OH group concentration of 200 ppm or more. This suppresses, for example, ion sputtering or ion-assisted etching on the reaction tube wall protection plate 110, as compared to a component made of, for example, high-purity electrically fused quartz glass, and suppresses the occurrence of localized stress on the surface of the reaction tube wall protection plate 110. Accordingly, breakage of the reaction tube wall protection plate 110 due to such stress is suppressed. That is, the replacement frequency of the reaction tube wall protection plate 110 may be reduced.

The reaction tube wall protection plate 110 is disposed in a space between the inner wall surface of the electrode installation portion 1a and the substrates W, and is arranged so as to cover the electrode installation portion 1a. That is, the reaction tube wall protection plates 110 are respectively arranged so as to cover the inner wall surfaces (i.e., the inner wall surface sides of the electrode installation portions 1a and 1b) opposite to the outer wall surfaces of the reaction tube 1 (i.e., the outer wall surface sides of the electrode installation portions 1a and 1b) where the pair of electrodes 31A and 31B are installed. This prevents ions from the plasma formed on the substrates W from entering the inner wall surfaces of the electrode installation portions 1a and 1b. Accordingly, the inner wall surfaces of the electrode installation portions 1a and 1b are prevented from being damaged by, for example, ion sputtering or ion-assisted etching, which suppresses the occurrence of localized stress on the surfaces of the electrode installation portions 1a and 1b. Even in the case where the reaction tube 1 is made of, for example, high-purity electrically fused quartz glass, consumption of the reaction tube 1 may be suppressed.

In addition, when the entire reaction tube 1 is made of synthetic quartz glass having an OH group concentration of 200 ppm or more, the cost of the reaction tube 1 increases due to factors such as difficulties in material procurement and processing. Similarly, even when only the electrode installation portions 1a and 1b of the reaction tube 1 are made of synthetic quartz glass having an OH group concentration of 200 ppm or more and the other portions are made of high-purity electrically fused quartz glass, the cost of the reaction tube 1 also increases.

In contrast, in the plasma processing apparatus according to the present embodiment, by adopting a structure in which the reaction tube wall protection plate 110 made of synthetic quartz glass having an OH group concentration of 200 ppm or more is disposed inside the reaction tube 1, the reaction tube 1 may be made of, for example, high-purity electrically fused quartz glass. This may suppress an increase in the cost of the reaction tube 1. In addition, when replacing the reaction tube 1, the procurement time of the reaction tube 1 may be shortened.

In addition, during maintenance, it is sufficient to replace the reaction tube wall protection member 100 or the reaction tube wall protection plate 110, and compared to replacing the entire reaction tube 1, maintenance cost and environmental load may be reduced.

The shape of the reaction tube wall protection plate 110 is an arc shape cut out from a cylindrical shape. This allows the arc-shaped reaction tube wall protection plate 110 to be disposed along the inner wall surface of the reaction tube 1.

However, the shape of the reaction tube wall protection plate 110 is not limited to this. As illustrated in FIGS. 3 to 6, the reaction tube wall protection plate 110 may be configured by combining plate-shaped components. Specifically, the reaction tube wall protection plate 110 may be formed by welding a plate-shaped portion 110b to one end in the width direction of a plate-shaped portion 110a, and welding a plate-shaped portion 110c to the other end in the width direction of the plate-shaped portion 110a. The plate-shaped portion 110b is bent toward the front surface side (i.e., the side facing the center of the reaction tube 1) with respect to the plate-shaped portion 110a, and the plate-shaped portion 110c is also bent toward the front surface side (i.e., the side facing the center of the reaction tube 1) with respect to the plate-shaped portion 110a. In this way, by arranging the multiple plate-shaped portions 110a to 110c in a bent state, the manufacturing cost of the reaction tube wall protection plate 110 may be reduced.

For example, the upper end of the reaction tube wall protection plate 110 (reaction tube wall protection member 100) may be formed to a position higher in the vertical direction than the upper end of the electrode 31A (e.g., by +20 cm). The lower end of the reaction tube wall protection plate 110 is formed to a position lower than the lower end of the electrode 31A in the vertical direction and further extends to the pedestal 120 that supports the reaction tube wall protection plate 110. In addition, the lower end of the reaction tube wall protection member 100 is formed to reach a bottom flange 1d of the reaction tube 1.

As illustrated in FIG. 3, for example, the width of the reaction tube wall protection plate 110 may be greater than the width of the electrode 31A (e.g., by +10 cm on each side).

The plate thickness of the reaction tube wall protection plate 110 (plate-shaped portions 110a, 110b, and 110c) may be in a range of, for example, 3 mm to 4 mm.

The rear surface side of the reaction tube wall protection plate 110 includes protrusions 115 formed by welding. The height of the protrusions 115 is, for example, 2 mm. For example, the protrusions 115 may be made of synthetic quartz glass having an OH group concentration of 200 ppm or more, as in the reaction tube wall protection plate 110.

The protrusions 115 are formed near the upper end on the rear surface of the reaction tube wall protection plate 110, and are also formed at the bent portions (welded portions) between the plate-shaped portion 110a and the plate-shaped portion 110b, and between the plate-shaped portion 110a and the plate-shaped portion 110c. When the reaction tube wall protection member 100 is installed in the reaction tube 1, the protrusions 115 come into contact with the inner wall surface of the reaction tube 1, and the upper portion of the reaction tube wall protection plate 110 is supported. As a result, as illustrated in, for example, FIG. 4, a gap is formed between the inner wall surface of the reaction tube 1 and the reaction tube wall protection plate 110.

The pedestal 120 supports the lower end of the reaction tube wall protection plate 110 installed to stand upright on the pedestal 120. A fixing shaft 125 that extends radially outward is provided on the rear surface side of the pedestal 120. For example, the pedestal 120 may be made of synthetic quartz glass having an OH group concentration of 200 ppm or more, as in the reaction tube wall protection plate 110. The fixing shaft 125 may also be made of synthetic quartz glass having an OH group concentration of 200 ppm or more, like the reaction tube wall protection plate 110. The pedestal 120 and/or the fixing shaft 125 may be made of high-purity electrically fused quartz glass, like the reaction tube 1.

When the reaction tube wall protection member 100 is mounted to the reaction tube 1, the pedestal 120 is placed on a bottom flange 1d that is provided at the lower end of the reaction tube 1 and extends inward, and the fixing shaft 125 is inserted into an opening port 1e formed in the side wall of the reaction tube 1. At this time, the protrusions 115 come into contact with the inner wall surface of the reaction tube 1. As a result, a gap is formed between the rear surface of the reaction tube wall protection plate 110 and the wall surface of the reaction tube 1. Then, the fixing shaft 125 is fixed by using a bottom flange 210, a retainer 220, a nut 230, and an O-ring 240, which are provided outside the reaction tube 1. A structure for fixing the reaction tube wall protection member 100 to the opening port 1e may be the same as the structure for fixing the gas supply pipe 20 to the opening port of the reaction tube 1.

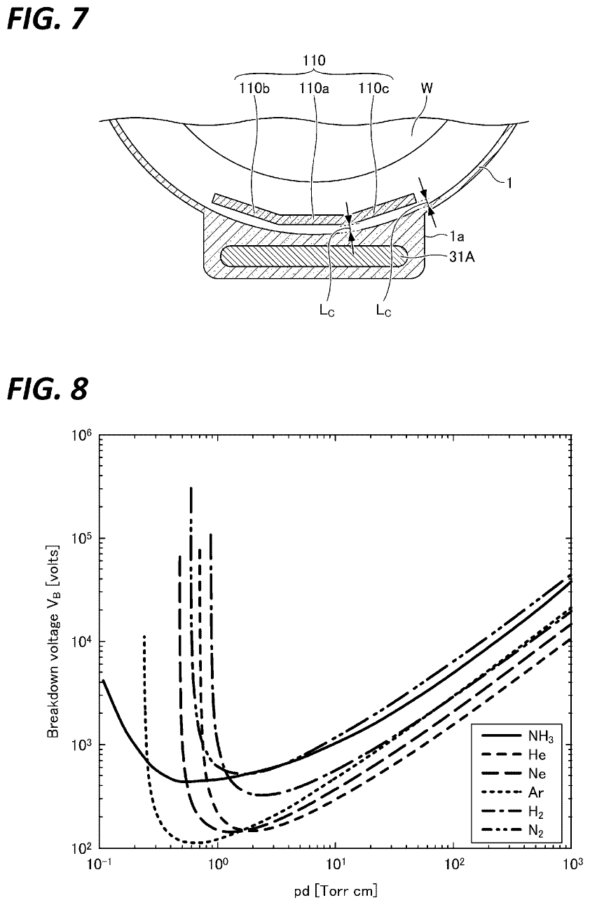

FIG. 7 is a transverse cross-sectional view illustrating an example of an arrangement of the reaction tube 1 and the reaction tube wall protection member 100.

As illustrated in FIG. 4, the protrusions 115 are formed on the outer peripheral side of the reaction tube wall protection plate 110. The reaction tube wall protection plate 110 is disposed such that the protrusions 115 come into contact with the inner wall surface of the reaction tube 1. Accordingly, as illustrated in FIG. 7, a gap L_{C} is formed between the inner wall surface of the reaction tube 1 and the rear surface of the reaction tube wall protection plate 110.

When dry cleaning is performed inside the reaction tube 1, the cleaning gas is also supplied into this gap, and the inner wall surfaces of the electrode installation portions 1a and 1b of the reaction tube 1, as well as the outer wall surface of the reaction tube wall protection plate 110, are also cleaned.

In addition, when performing plasma processing on the substrates W, for example, unintended discharge (abnormal discharge) does not occur between the inner wall surface of the reaction tube 1 and the outer wall surface of the reaction tube wall protection plate 110. In an embodiment, the gap L_{C} between the inner wall surface of the reaction tube 1 and the rear surface of the reaction tube wall protection plate 110 may be 2 mm or less.

FIG. 8 is a graph illustrating examples of Paschen curves. The horizontal axis represents the product of the gas pressure p [Torr] and the discharge gap distance d [cm], indicated as pd [Torr·cm]. The vertical axis represents VB [Volts], which is the voltage at which discharge starts (discharge start voltage or breakdown voltage) for each gas. Here, the gases represented as examples are NH₃, He, Ne, Ar, H₂, and N₂.

Here, the potential of the reaction tube wall protection member 100 (reaction tube wall protection plate 110) may be regarded as approximately 0 V. When the gas pressure p is, for example, 400 mTorr and the discharge gap distance d (i.e., the gap L_{C}) is 2 mm, then pd=0.08 Torr cm (i.e., 1×10⁻¹ Torr·cm or less). As illustrated in FIG. 8, at pd=1×10⁻¹ Torr·cm, the discharge start voltage for NH₃ is about 4,000 V. That is, when the gas pressure p is 400 mTorr, and the discharge gap distance d (gap L_{C}) is 2 mm or less, the discharge start voltage is 4,000 V or more for any of the gases NH₃, He, Ne, Ar, H₂, and N₂. In this apparatus, the maximum radio-frequency voltage applied to the electrodes 31A and 31B is less than 4,000 V. Therefore, by setting the gap L_{C} between the inner wall surface of the reaction tube 1 and the rear surface of the reaction tube wall protection plate 110 to 2 mm or less, abnormal discharge may be prevented from occurring on the rear surface side of the reaction tube wall protection plate 110. As a result, the inner wall surface of the reaction tube 1 may be prevented from being damaged by abnormal discharge.

According to an aspect, it may be possible to provide a plasma processing apparatus and a reaction tube wall protection member that suppress consumption of a reaction tube.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a reaction tube having a cylindrical shape;
a substrate holder configured to hold a plurality of substrates stacked in multiple stages and to be inserted into and removed from the reaction tube;
a pair of electrodes disposed outside the reaction tube and arranged to face each other across a center of the reaction tube;
a radio-frequency power supply configured to generate plasma in the reaction tube by applying radio-frequency power to one or both of the pair of electrodes; and
a pair of reaction tube wall protection enclosures including a first reaction tube wall protection enclosure disposed between one of the pair of electrodes and the substrate holder, and a second reaction tube wall protection enclosure disposed between a remaining one of the pair of electrodes and the substrate holder,
wherein the pair of reaction tube wall protection enclosures are configured to cover respective inner wall surfaces of the reaction tube that are opposite to outer wall surfaces of the reaction tube on which the pair of electrodes are installed.

2. The plasma processing apparatus according to claim 1, wherein the pair of reaction tube wall protection enclosures respectively include reaction tube wall protection plates that cover inner wall surfaces of the reaction tube that are opposite to outer wall surfaces on which the pair of electrodes are installed, and
each of the reaction tube wall protection plates is made of synthetic quartz glass having an OH group concentration of 200 ppm or more.

3. The plasma processing apparatus according to claim 2, wherein the reaction tube is made of electrically fused quartz glass.

4. The plasma processing apparatus according to claim 2, wherein each of the reaction tube wall protection plates has a structure in which a plurality of plate-shaped portions are bent and connected.

5. The plasma processing apparatus according to claim 2, wherein each of the reaction tube wall protection plates has an arc shape.

6. The plasma processing apparatus according to claim 2, wherein each of the reaction tube wall protection plates includes, on a rear surface side thereof, a protrusion that comes into contact with an inner wall surface of the reaction tube.

7. The plasma processing apparatus according to claim 6, wherein a gap between the rear surface of each of the reaction tube wall protection plates and the inner wall surface of the reaction tube is 2 mm or less.

8. The plasma processing apparatus according to claim 2, wherein each of the reaction tube wall protection plates has a width greater than a width of the electrodes.

9. The plasma processing apparatus according to claim 2, wherein an upper end of each of the reaction tube wall protection plates is positioned higher than an upper end of the electrodes, and
a lower end of each of the reaction tube wall protection plates is positioned lower than a lower end of the electrodes.

10. A reaction tube wall protection enclosure disposed inside a reaction tube of a plasma processing apparatus, the plasma processing apparatus including a tubular reaction tube, a substrate holder configured to hold a plurality of substrates stacked in multiple stages and to be inserted into and removed from the reaction tube, a pair of electrodes disposed outside the reaction tube and arranged to face each other across a center of the reaction tube, and a radio-frequency power supply configured to generate plasma in the reaction tube by applying radio-frequency power to the pair of electrodes or to one of the pair of electrodes,
the reaction tube wall protection enclosure comprising:
a reaction tube wall protection plate made of synthetic quartz glass having an OH group concentration of 200 ppm or more and configured to cover an inner wall surface of an electrode installation portion of the reaction tube on which each of the electrodes is installed; and
a pedestal configured to support the reaction tube wall protection plate.

11. The reaction tube wall protection enclosure according to claim 10, wherein a protrusion is provided on a rear surface of the reaction tube wall protection plate, the protrusion being into contact with an inner wall surface of the reaction tube.
